(19) United States
(12) Patent Application Publication
(10) Pub. No.: US 2026/0336467 A1
(43) Pub. Date: Oct. 29, 2026

(54) BATTERY CAPACITY CHECK METHODS AND SYSTEMS FOR AIRWORTHINESS DETERMINATION

(71) Applicant: Electric Power Systems, Inc., North Logan, UT (US)

(72) Inventors: Jeffrey Belt, Smithfield, UT (US); Michael Armstrong, North Logan, UT (US); Suresh Jayagondar, Hyde Park, UT (US)

(73) Assignee: Electric Power Systems, Inc., North Logan, UT (US)

(21) Appl. No.: 19/114,180

(22) PCT Filed: Sep. 22, 2023
(86) PCT No.: PCT/US2023/033494

§ 371 Date: Mar. 21, 2025

Related U.S. Application Data
(60) Provisional application No. 63/409,567, filed on Sep. 23, 2022.

(51) Int. Cl. B60L 58/12; B60L 53/20; H01M 10/42; H02J 7/82

(52) U.S. Cl. CPC B60L 58/12; B60L 53/20; H01M 10/425; H02J 7/82; B60L 2200/10; B60L 2210/10; H01M 2010/4271; H01M 2220/20

(57) ABSTRACT

A charging system can comprise a processor configured to perform capacity checks at predetermined intervals. The capacity checks can include commanding, via a processor, charging each cell in the battery module at a first constant rate to a first voltage; commanding, via the processor, tapering of a charge at a constant voltage until a current reaches a predetermined amperage; commanding, via the processor, discharging the battery module to a second voltage; and determining, via the processor, a capacity of the battery module in response to the discharging.

### FIELD OF INVENTION

The present disclosure generally relates to apparatus, systems and methods for checking a capacity of battery modules of an aircraft battery system for airworthiness.

### BACKGROUND OF THE INVENTION

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may be inventions.

The state of health (SOH_{c}) of a battery module describes the difference between a battery module being studied after being used for a period of time and the battery module in a newly manufactured state. In this regard, a battery module's state of health takes into account the aging of cells disposed in the battery module. SOH_{c} is defined as a ratio of an estimated maximum capacity for a particular battery over the rated capacity for that battery. As batteries are increasingly being used in aviation, especially as a primary energy source for propulsion, accurate and consistent SOH_{c} determinations is becoming increasingly important.

### SUMMARY OF THE INVENTION

A battery management system is disclosed herein. In various embodiments, the battery management system includes a tangible, non-transitory computer-readable storage medium having instructions stored thereon that, in response to execution by one or more processors, cause the one or more processors to perform operations comprising: performing, by the one or more processors, a capacity check cycle on a battery system, the battery system configured to power a propulsion system of an electrically powered aircraft, the capacity check cycle including: establishing, by the one or more processors, a first initial state of charge of the battery system, charging, by the one or more processors and through a charging system, the battery system to a first voltage, and discharging, by the one or more processors, the battery system to a second voltage; and calculating an estimated battery capacity of the battery system based on battery data from the capacity check cycle.

A method for performing a capacity check of an aircraft battery system is disclosed herein. The method can comprise: establishing a first initial state of charge of a battery module; charging each cell in the battery module at a first constant rate to a first voltage; a taper of the charging until a current reaches a set amperage; discharging the battery module to a second voltage; recharging the battery module to a second initial state of charge; determining a capacity percentage of the battery module; and comparing the capacity percentage of the battery module to a threshold capacity percentage for an airworthiness standard.

A charging system is disclosed herein. In various embodiments, the charging system comprises: a battery system comprising a first plurality of battery modules; a battery management system including a controller in operable communication with the first plurality of battery modules, the controller operable to: receive, via one or more processors of the controller, a number of flight cycles of an aircraft battery system; conduct, via the one or more processors, a capacity check of each battery module of a plurality of battery modules in the aircraft battery system; and compile, via the one or more processors, a capacity data for the plurality of battery modules in the aircraft battery system.

An article of manufacture is disclosed herein. In various embodiments, the charging system includes a tangible, non-transitory computer-readable storage medium having instructions stored thereon that, in response to execution by one or more processors, cause the one or more processors to perform operations comprising: receiving, via the one or more processors, a number of flight cycles that an aircraft battery system has powered an aircraft, the aircraft battery system including a plurality of battery modules including a battery module; determining, via the one or more processors, the aircraft battery system is scheduled for a capacity check based on the number of flight cycles; commanding, via the one or more processors, charging each cell in the battery module at a first constant rate (or variable rate) to a first voltage; commanding, via the one or more processors, taper of the charging until a current reaches a predetermined amperage; commanding, via the one or more processors, discharging the battery module to a second voltage; and determining, via the one or more processors, a capacity of the battery module in response to the discharging.

### BRIEF DESCRIPTION OF THE DRAWINGS

A more complete understanding of the present disclosure may be derived by referring to the detailed description and claims when considered in connection with the Figures, wherein like reference numbers refer to similar elements throughout the Figures, and where:

FIG. 1 illustrates a perspective view of a battery system, in accordance with various embodiments;

FIG. 2 illustrates an interconnected battery module for use in a battery system, in accordance with various embodiments;

FIG. 3 illustrates a schematic view of a charging ecosystem, in accordance with various embodiments;

FIG. 4 illustrates a schematic view of a charging ecosystem, in accordance with various embodiments;

FIG. 5 illustrates a schematic view of a portion of a charging ecosystem, in accordance with various embodiments;

FIG. 6 illustrates a method for maintaining an aircraft battery system, in accordance with various embodiments;

FIG. 7 illustrates a process for performing a capacity check for a battery module of an aircraft battery system, in accordance with various embodiments;

FIG. 8 illustrates a process for conducting various capacity checks for a battery module of an aircraft battery system, in accordance with various embodiments;

FIG. 9 illustrates a plot of capacity percentage as a function of flight cycles for a battery module of an aircraft battery system, in accordance with various embodiments;

FIG. 10 illustrates a process for setting a maintenance interval for an electrically powered aircraft, in accordance with various embodiments;

FIG. 11 illustrates a process for replacing a battery system of an electrically powered aircraft, in accordance with various embodiments; and

FIG. 12 illustrates a process for calibrating a capacity percentage of an electric aircraft, in accordance with various embodiments.

### DETAILED DESCRIPTION

The following description is of various example embodiments only, and is not intended to limit the scope, applicability, or configuration of the present disclosure in any way. Rather, the following description is intended to provide a convenient illustration for implementing various embodiments including the best mode. As will become apparent, various changes may be made in the function and arrangement of the elements described in these embodiments, without departing from the scope of the appended claims. For example, the steps recited in any of the method or process descriptions may be executed in any order and are not necessarily limited to the order presented. Moreover, many of the manufacturing functions or steps may be outsourced to or performed by one or more third parties. Furthermore, any reference to singular includes plural embodiments, and any reference to more than one component or step may include a singular embodiment or step. Also, any reference to attached, fixed, connected or the like may include permanent, removable, temporary, partial, full and/or any other possible attachment option. As used herein, the terms “coupled,” “coupling,” or any other variation thereof, are intended to cover a physical connection, an electrical connection, a magnetic connection, an optical connection, a communicative connection, a functional connection, and/or any other connection.

For the sake of brevity, conventional techniques for mechanical system construction, management, operation, measurement, optimization, and/or control, as well as conventional techniques for mechanical power transfer, modulation, control, and/or use, may not be described in detail herein. Furthermore, the connecting lines shown in various figures contained herein are intended to represent example functional relationships and/or physical couplings between various elements. It should be noted that many alternative or additional functional relationships or physical connections may be present in a modular structure.

A “battery system” as referred to herein includes a plurality of battery modules electrically coupled together and configured to power an electric vehicle, a plurality of strings of battery modules that form the plurality of battery modules electrically coupled together and configured to power the electric vehicle, a single string of battery modules from the plurality of strings of battery modules, a single battery module from the string of battery modules, or the like. The present disclosure is not limited in this regard.

A “battery capacity” as described herein, refers to a ratio of a measured capacity, or estimated capacity (i.e., a battery system capacity at a point in time) to a rated capacity (i.e., an initial battery system capacity of a newly manufactured battery system).

For a battery system, it is important to evaluate remaining capacity also referred often as state of health. State of health (“SOH_{c}”) as described herein refers to a ratio of estimated battery capacity for a particular battery system to the rated capacity for that battery system. To determine an airworthiness for a battery system, SOH_{c} of a battery system has to be capable of meeting mission standards. Disclosed herein is a method, and system for implementing the method, to estimate a remaining capacity (i.e., SOH_{c}) of a battery system of an electric vehicle (e.g., an electrically powered aircraft).

In various embodiments, a method of checking a capacity of a battery system comprises fully charging the battery system at a nominal temperature and fully discharging the battery system at the nominal temperature at regular intervals. In various embodiments, a full (or nearly full) capacity measurement can result from the method disclosed herein (measured in Ampere-hours and Watt-hours). The measurement (or calculation) from the method disclosed herein can give an estimation for the remaining capacity retained at each point in time for a given battery system. In various embodiments, the method disclosed herein can give an indication of not only a rate of degradation (if it is abnormal) but also an expected number of flight cycles until a capacity check should be performed again (i.e., a next maintenance interval).

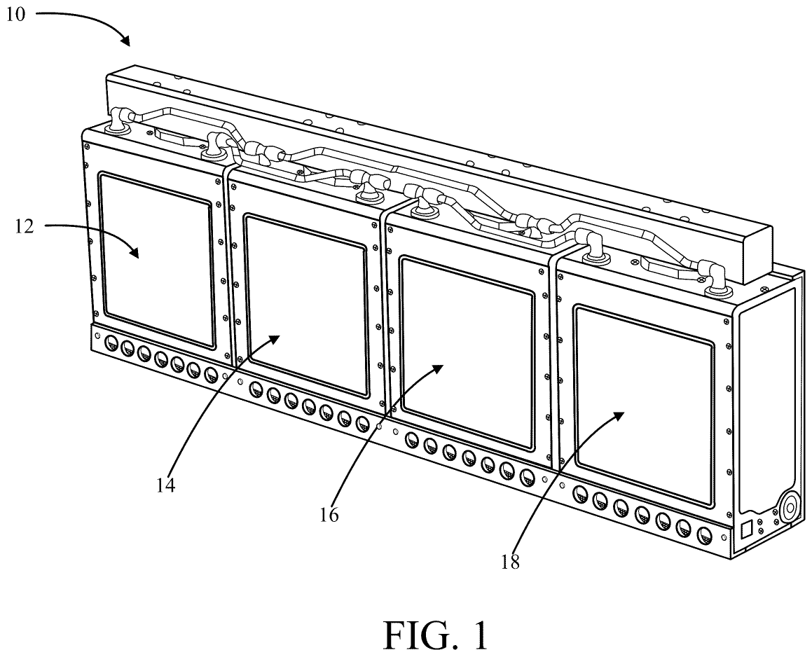

Referring now to FIG. 1, a perspective view of a portion of a battery system 10 (e.g., an interconnected battery system) is illustrated, in accordance with various embodiments. The battery system 10 includes a plurality of interconnected battery modules (“ICBM” or “ICBMs”) (e.g., interconnected battery modules 12, 14, 16, 18). Each of the interconnected battery modules (e.g., ICBMs 12, 14, 16, 18) includes a plurality of cells disposed therein. The plurality of cells may be cylindrical cells, prismatic cells, pouch cells, or any other cell. In various embodiments, each of the plurality of cells are pouch cells.

In various embodiments, an ICBM (e.g., ICBMs 12, 14, 16, 18) as disclosed herein may comprise a nominal voltage of approximately 7 volts, a capacity of approximately 50 ampere-hours, an energy output of approximately 0.36 kWh, or the like. Although an example ICBM may have these specifications, an interconnected battery module of any specification is within the scope of this disclosure. In an example embodiment, a 1,000-volt interconnected battery module system may be created by interconnecting one-hundred and thirty-six ICBMs in series. In various embodiments, by having each ICBM isolated and discrete from the remaining ICBMs, a thermal runaway event may be limited to a single ICBM where the thermal runaway event occurs. In this regard, in accordance with various embodiments, an ICBM, as disclosed herein, may be configured to contain a thermal runaway event of a cell disposed in the ICBM without affecting any cell in any of the remaining ICBMs.

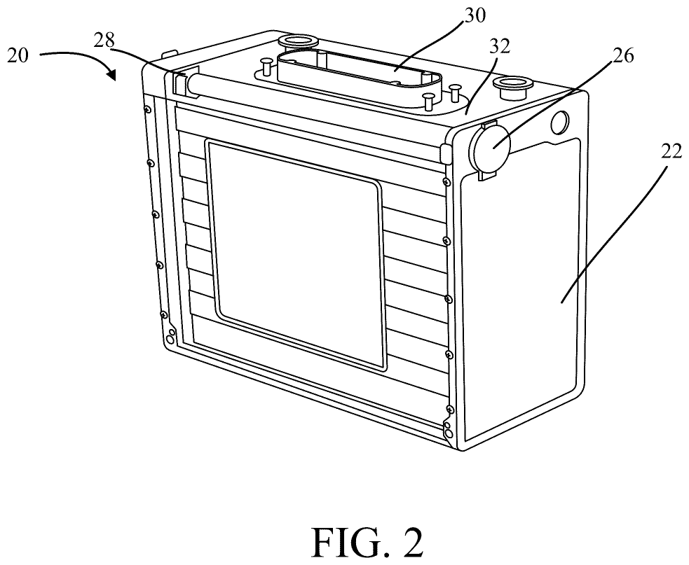

Referring now to FIG. 2, a perspective view of an ICBM 20 is illustrated, in accordance with various embodiments. In various embodiments the ICBM 20 includes a housing 22 and a plurality of cells disposed in the housing 22. In various embodiments, the plurality of cells are a plurality of pouch cells. In various embodiments, the ICBM 20 includes a positive terminal 26 disposed on a first side of the housing 22 and a negative terminal 28 disposed on a second side of the housing 22.

In various embodiments, the positive terminal 26 is configured to electrically, and physically, couple to a negative terminal (e.g., negative terminal 28) of an adjacent ICBM in an interconnected battery system (e.g., battery system 10 from FIG. 1). Similarly, the negative terminal 28 is configured to electrically, and physically, couple to a positive terminal (e.g., positive terminal 26) of an adjacent ICBM in an interconnected battery system (e.g., battery system 10 from FIG. 1). In this regard, the ICBMs of battery system 10 may be configured for electrical and physical coupling in series electrically and may be configured with an additional component to create a parallel electrical connection, in accordance with various embodiments. The present disclosure is not limited in this regard. For example, the interconnected battery system may be configured to couple adjacent ICBMs in parallel as a default configuration instead of in series as a default configuration and still be within the scope of this disclosure.

In various embodiments, the housing 22 includes a vent port 30. In various embodiments, the vent port 30 is a fluid outlet in the plurality of fluid outlets in a battery system 10 from FIG. 1. In various embodiments, the vent port 30 is disposed on a top surface of the housing. The vent port 30 is in fluid communication with an internal cavity 32 of the housing 22. The plurality of cells are also disposed in the internal cavity 32. In this regard, any ejecta, gases, or foreign object debris (“FOD”) from a thermal runaway event may be configured to be expelled out the vent port 30 and into a common vent and out of the interconnected battery system (e.g., battery system 10 from FIG. 1).

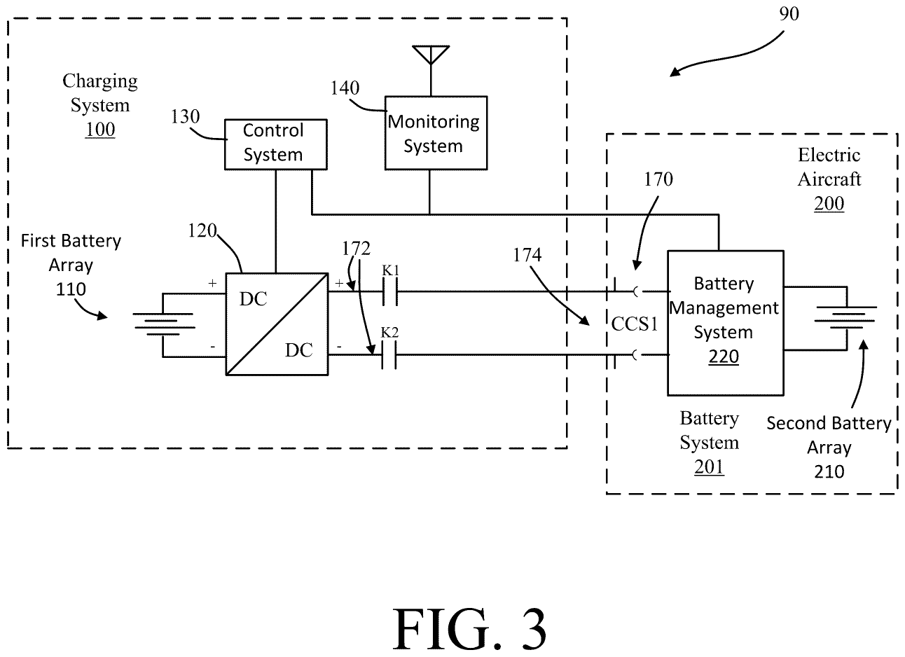

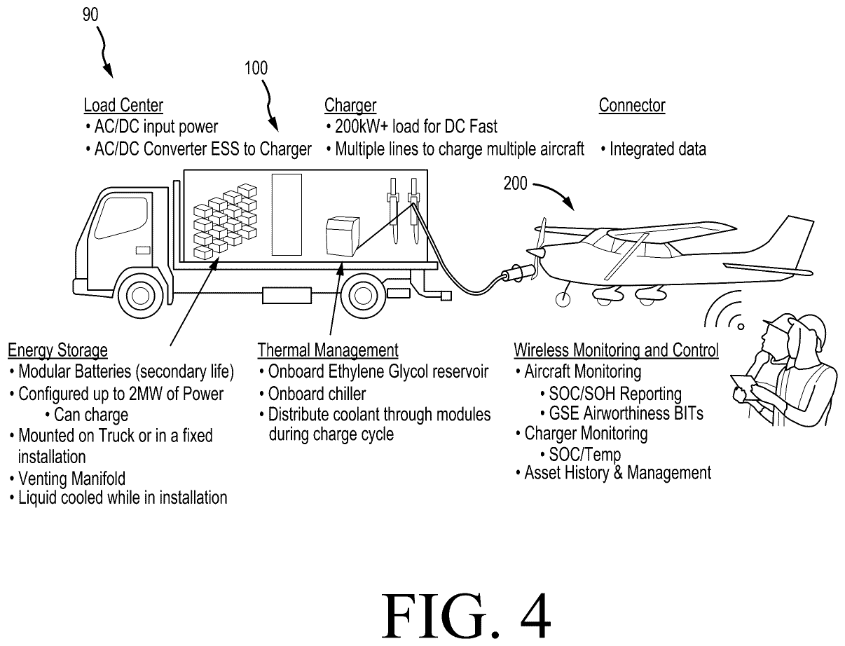

Referring now to FIGS. 3 and 4, a schematic view (FIG. 3) and a side view (FIG. 4) of an electric vehicle charging ecosystem 90 is illustrated, in accordance with various embodiments. The electric vehicle charging ecosystem 90 may be configured for charging an electric aircraft 200 (e.g., an electrically powered aircraft). The electric vehicle charging ecosystem 90 comprises a charging system 100 (e.g., a mobile microgrid charging system) and the electric aircraft 200 having a battery system 201.

In various embodiments, the charging system 100 is a mobile charging system. A “mobile charging system” as referred to herein refers to a battery system fixedly coupled to a wheeled vehicle (e.g., a truck, a lift, a van, a bus, a specialty vehicle, or the like), a non-wheeled vehicle (e.g., vehicle with continuous track system, train system, or the like), or the like. In this regard, the mobile charging system may be configured to be transported from a fixed charging station (e.g., configured to charge the charging system 100) to a vehicle (e.g., electric aircraft 200) being charged via the charging system 100. Although described herein as a mobile charging system, the present disclosure is not limited in this regard. For example, a stationary, fixed, and/or non-moveable charging system is within the scope of this disclosure, in accordance with various embodiments.

The charging system 100 comprises a first battery array 110. Similarly, the electric aircraft 200 comprises the battery system 201 including a second battery array 210. “Battery array” as described herein is not meant to be limiting to any shape, configuration, or the like. “Battery array” as described herein refers to a plurality of battery modules (e.g., ICBM 20 from FIG. 2) excluding any control modules (e.g., a battery management system, or any other type of control module in a battery system). Stated another way, a “battery array” as described herein refers to a plurality of interconnected battery modules (e.g., ICBM 20 from FIG. 2). Although the charging system 100 is described as including a first battery array 110, the present disclosure is not limited in this regard. For example, the charging system can include a bi-directional grid interface as a fixed charging station that is directly coupled to an electrical grid, in accordance with various embodiments.

In various embodiments, the first battery array 110 comprises a plurality of battery modules (e.g., ICBM 20 from FIG. 2). Similarly, the second battery array 210 comprises a plurality of battery modules (e.g., ICBM 20 from FIG. 2). In this regard, as described further herein, the battery modules of the electric aircraft 200 and the battery modules of the charging system can be cross-compatible, in accordance with various embodiments. “Cross-compatible” as defined herein refers to being replaceable with, or swappable with (i.e., a battery module in the second battery array 210 could be swapped with a battery module in the first battery array 110 and vice versa). Although referred to herein as “battery arrays” any system of interconnected battery modules is within the scope of this disclosure. Thus, the term “array” is not a term limiting shape, or configuration, or the like for the battery systems disclosed herein, in accordance with various embodiments.

In various embodiments, charging system 100 comprises the first battery array 110, a bi-directional direct current (DC)/DC converter 120, a control system 130, and a monitoring system 140. In various embodiments, the control system 130 is a battery management system for the charging system 100. In this regard, the control system 130 can manage a charging and discharging of the first battery array 110, store data corresponding to battery capacity checks, as described further herein, facilitate the battery capacity checks, as described further herein, or the like. The present disclosure is not limited in this regard.

The charging system 100 is configured to charge the second battery array 210 of the electric aircraft 200 via control system 130 (e.g., a battery management system) and through the first battery array 110. In various embodiments, the first battery array 110 may be configured to be charged via a fixed electrical grid (e.g., configured to receive AC/DC input power) or the like. In various embodiments, the bi-directional DC/DC converter 120 is in operable communication with the control system 130. In this regard, the control system 130 may be configured to control charging of the second battery array 210 by the first battery array 110 through the DC/DC converter 120. In various embodiments, the first battery array 110 may be mounted within a vehicle (e.g., a truck or the like as shown in FIG. 4). In various embodiments, the first battery array 110 is a component of an energy storage system of the charging system 100.

In various embodiments, the electric vehicle charging ecosystem 90 comprises a combined charging system (CCS) 170 configured for high-power DC fast charging. Although illustrated as comprising a United States style combined charging system (“CCS1”) charging system, the charging system is not limited in this regard. For example, the combined charging system 170 may comprise a European style combined charging system (“CCS2”), Chademo, GBT, or any other emerging aerospace standard charging system, in accordance with various embodiments.

In various embodiments, the charging system 100 includes electrical cables 172. The electrical cables 172 extend from the bi-directional DC/DC converter 120 to a combo plug 174 of the combined charging system 170. The combo plug of the combined charging system 170 is configured to be electrically coupled to a socket of the combined charging system 170. In various embodiments, the combo plug is a component of the charging system 100 and the socket is a component of the electric aircraft 200 or vice versa. The present disclosure is not limited in this regard.

In various embodiments, the bi-directional DC/DC converter 120 is configured to act as an impedance matching device. Additionally, the bi-directional DC/DC converter 120 is configured to allow power to be shuttled to and from the second battery array 210 of the battery system 201 of the electric aircraft 200, thereby enabling advanced battery state of health estimation at every charge cycle, in accordance with various embodiments. Thus, each charge cycle may be an opportunity to assess the SOH_{c} of each battery module in the second battery array 210 of the battery system 201 of the electric aircraft 200, which may be utilized to commission each battery module prior to each flight, as described further herein.

In various embodiments, the control system 130 can further comprise a supervisory control and data acquisition system (“SCADA”). In this regard, the SCADA system may be configured to monitor and control processes of the charging system 100 (e.g., locally, from a remote location, or the like).

In various embodiments, the monitoring system 140 is in operable communication with a battery management system 220 in response to the monitoring system 140 being electrically coupled to the battery management system 220 or in response to the electric aircraft 200 becoming in range of a wireless network of the monitoring system. In various embodiments, the monitoring system 140 comprises remote telemetry (i.e., a remote telemetry unit (“RTU”) with a microprocessor-based remote device configured to monitor and report events of the battery management system 220). The monitoring system 140 may be configured to communicate with the battery management system 220 of the electric aircraft 200 through a wireless or wired connection. In various embodiments, the monitoring system 140 may be configured to transmit any data received during a charging event or the like to external servers for data collection through wireless or wired connections. The present disclosure is not limited in this regard. In various embodiments, the battery management system 220 communicates with the monitoring system 140 via a wireless network. In this regard, in response to the battery management system 220 becoming in range of the wireless network, the battery management system 220 may be configured to transfer information related to operation history of the second battery array 210 to the monitoring system 140. Accordingly, battery modules within the second battery array 210 may be continually monitored for airworthiness, in accordance with various embodiments.

Moreover, charging system 100 (e.g., a mobile charging system), optionally in connection with a remote system, may be configured to charge and/or discharge the first battery array 110 and the second battery array 210 and in connection with that charging and/or discharging, to determine a SOH_{c} of each of the first battery array 110, the second battery array 210, and individual battery modules within each array. Thus, the SOH_{c} of each module of the first and second battery arrays can be known each time the aircraft is connected to charging system 100, and the desirability of swapping of batteries can be assessed in real-time at each aircraft charging session. In addition, if swapping is indicated as desirable, the swap out module is already located in proximity to the aircraft and its current SOH_{c} is known.

In various embodiments, SOH_{c} may be determined by measured methods, predicted methods, or a combination of measured and predicted methods. In various embodiments, the SOH_{c} may be determined from a voltage differential measured under a load and used to measure internal impedance. In various embodiments, the SOH_{c} may be determined based on measured energy supplied or received during a large depth of discharge cycle. In various embodiments, the SOH_{c} may be determined based on a Department of Defense capacity test. The present disclosure is not limited in this regard.

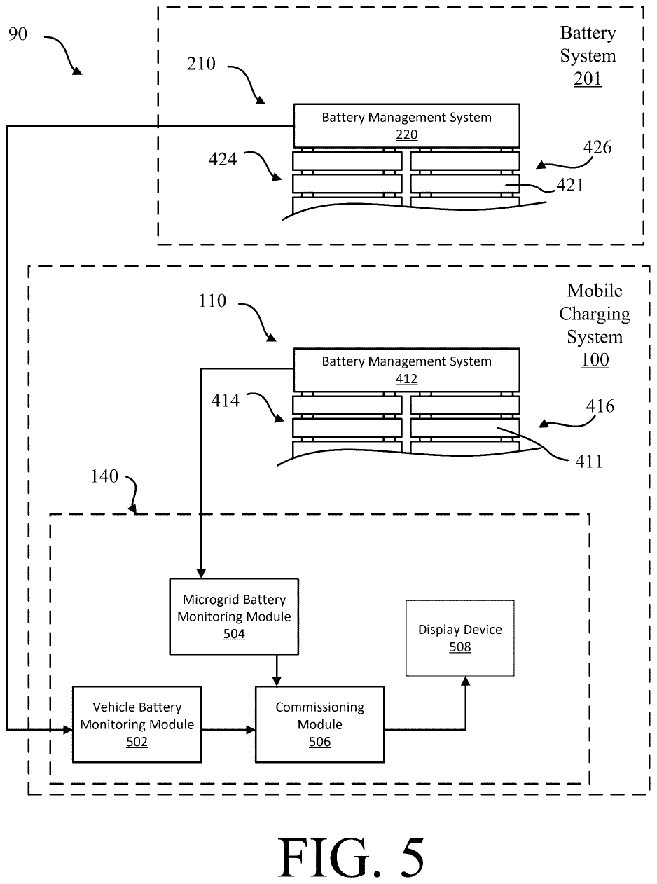

Referring now to FIG. 5, a schematic view of a portion of the electric vehicle charging ecosystem 90 from FIGS. 3 and 4 is illustrated, in accordance with various embodiments. In various embodiments, the first battery array 110 of the charging system 100 comprises a battery management system 412, a first string of battery modules 414 and a second string of battery modules 416. Similarly, the second battery array 210 of the battery system 201 for the electric aircraft 200 comprises a battery management system 220, a first string of battery modules 424 and a second string of battery modules 426. Although illustrated as comprising a single battery management system and two strings of battery modules for both the first battery array 110 and the second battery array 210, the present disclosure is not limited in this regard. For example, the first battery array 110 may comprise any number of strings of battery modules and/or any number of battery management systems. Similarly, the second battery array 210 may comprise any number of strings of battery modules and/or any number of battery management systems.

The charging system 100 comprises a plurality of battery modules (e.g., ICBMs 20 from FIG. 2) in the first string of battery modules 414 and a plurality of battery modules (e.g., ICBMs 20 from FIG. 2) in the second string of battery modules 416. Similarly, the battery system 201 comprises a plurality of battery modules (e.g., ICBMs 20 from FIG. 2) in the first string of battery modules 424 and a plurality of battery modules in the second string of battery modules 426 (e.g., ICBMs 20 from FIG. 2). The battery modules of charging system 100 are the same as the battery modules of the battery system 201. For example, if ICBMs 20 from FIG. 2 are utilized in the charging system 100, ICBMs 20 are also used in battery system 201. In this regard, battery modules in the first battery array 110 and the second battery array 210 are swappable, or interchangeable, as described further herein. In this regard, a single consistent ICBM may be utilized throughout the electric vehicle charging ecosystem 90. Thus, the battery modules used in the first battery array 110 and second battery array 210 have the same physical structure and dimensions, the same connectors, and are operably swappable.

In various embodiments, the charging system 100 may include a first discharge profile and the battery system 201 may include a second discharge profile. In various embodiments, the second discharge profile the battery system 201 may comprise a greater discharge rate relative to the first discharge profile of the charging system 100. For example, the second discharge profile may be about three times the first discharge profile or greater, or about five times the first discharge profile or greater, in accordance with various embodiments. In this regard, a greater discharge rate may be desirable for an aircraft system due to impact of weight on aircrafts capabilities.

In various embodiments, the charging system 100 comprises a battery capacity that is greater than the battery capacity of the battery system 201. In various embodiments, a C-rate experienced by the charging system 100 may be less than a C-rate experienced by the battery system 201 during discharging.

In various embodiments, the charging system 100 is configured to monitor each ICBM in the second battery array 210 and compare each ICBM to an airworthiness standard. For example, in response to the battery system 201 being electrically coupled to the monitoring system 140 (i.e., during charging of the electric aircraft 200 from FIG. 3), a vehicle battery monitoring module 502 of the charging system 100 may receive battery data for each ICBM in the second battery array 210 of battery system 201 via the battery management system 220. In various embodiments, the battery management system 220 is configured to manage a charge rate when the battery system 201 is being charged by an electrical grid.

In various embodiments, the vehicle battery monitoring module 502 may send the battery data for each ICBM in the second battery array 210 to a commissioning module 506. The sent battery data may be real-time data measured during the time when the aircraft is connected to or in proximity of the charging system 100, or the data may be data stored during operation of the aircraft remote from the charging system 100 (e.g., while flying) and sent when later in proximity or connected to the charging system 100. In this regard, the commissioning module 506 compares the battery data to the airworthiness standard. The battery data may include discharge data, shock and vibration data, whether the ICBM was ever over-discharged, over current, or the like. The battery data may be tied directly to the airworthiness standard.

Similarly, the charging system 100 is configured to continually (or periodically) monitor each ICBM in the first battery array 110 and compare each ICBM to an airworthiness standard. However, the present disclosure is not limited in this regard. For example, the charging system 100 can monitor each ICBM in the first battery array 110 in response to receiving a command or the like and still be within the scope of this disclosure. The battery management system 412 of the first battery array 110 is continuously in electronic communication with a microgrid battery monitoring module 504 of the charging system 100. In this regard, the microgrid battery monitoring module 504 may receive battery data for each ICBM in the first battery array 110 of charging system 100 via the battery management system 412 continually, periodically, or in response to a testing (or monitoring) command.

In various embodiments, the vehicle battery monitoring module 502 may send the battery data for each ICBM in the second battery array 210 to a commissioning module 506. In this regard, the commissioning module 506 may classify each ICBM in the first battery array 110 as “swappable” or “non-swappable” based on comparing the battery data to a second airworthiness standard. “Swappable” as referred to herein means an ICBM of the first battery array 110 is suitable for replacing an ICBM in the second battery array 210 of the battery system 201. The second airworthiness standard may be greater than the airworthiness standard for the battery system 201. In this regard, for an ICBM in the first battery array 110 to be classified as “swappable” the ICBM should meet an initial, or starting, standard for incorporation into an electric aircraft 200 from FIGS. 3 and 4.

The battery data received by the microgrid battery monitoring module 504 may include discharge data, shock and vibration data, whether the ICBM was ever over-discharged, over current, or the like. The battery data may be tied directly to the airworthiness standard.

In this regard, when charging a battery system 201 of an electric aircraft 200 from FIGS. 3 and 4, if an ICBM 421 in the second battery array 210 of the battery system 201 no longer meets an airworthiness standard, a maintenance person can swap an ICBM 411 in the charging system 100 that is classified as “swappable” by the commissioning module 506, with the ICBM 421. Thus, the maintenance person can swap out the ICBM 421 with the ICBM 411 in a quick and/or efficient manner. In this regard, the charging system 100 may be configured to provide an on-site inventory management for the battery system 201, in accordance with various embodiments. Thus, the first battery array 110 of the charging system 100 may include a set of ICBMs that are being utilized for secondary life and/or a set of battery modules that are being utilized initially and act as inventory in case an ICBM of a battery system 201 for an electric aircraft 200 has to be replaced because it no longer meets the airworthiness standard.

Although described herein as being performed at a battery module level, the commissioning module 506 of the charging system 100 is not limited in this regard. For example, the commissioning module 506 can be configured to perform a commissioning process at an overall battery system level, a string of battery modules level, the battery module level, or the like and still be within the scope of this disclosure. In various embodiments, the commissioning module 506 performs the commissioning for the entire battery system that is configured to power the electrically powered aircraft. In various embodiments, the commissioning module 506 performs commissioning for each string of battery modules that forms a respective overall battery system.

In various embodiments, an ICBM 421 in the string of battery modules 424, 426 of the second battery array 210 of the battery system 201 may be configured for a secondary life with the charging system 100. For example, upon determining ICBM 421 no longer meets the airworthiness standard, the ICBM 421 may be disposed in the first battery array 110 of charging system 100 and continue to be utilized for charging the battery system 201. Thus, once an ICBM 421 no longer meets the airworthiness standard, the ICBM may still qualify to be used on the charging system 100, since the ICBM may be significantly less strained during use (i.e., operating a significantly slow discharge profile, not being subject to shock and vibration of an aircraft, or the like).

In various embodiments, an ICBM 411 in the string of battery modules 414, 416 of the first battery array 110 of the charging system 100 may be configured for a primary life in the second battery array 210 of the battery system 201. For example, to meet an airworthiness standard for the primary life, an ICBM 411 disposed in the first battery array 110 of the charging system 100 may include heightened criteria relative to a standard for use in the second battery array 210 of the battery system 201, such as having a relatively greater actual capacity relative to a design capacity (i.e., current capacity/design capacity), never experiencing shock and vibrations above a threshold level, never being over-discharged or over current, or the like. In this regard, the systems and methods disclosed herein may further sustainability of battery modules and battery systems relative to typical battery modules and systems.

In various embodiments, the commissioning module 506 is in electronic communication with a display device 508. The display device 508 may comprise any suitable hardware, software, and/or database components capable of sending, receiving, and storing data. For example, display device 508 may comprise a personal computer, personal digital assistant, cellular phone, smartphone (e.g., IPHONE®, BLACKBERRY®, and/or the like), IoT device, kiosk, and/or the like. Display device 508 may comprise an operating system, such as, for example, a WINDOWS® mobile operating system, an ANDROID® operating system, APPLE® IOS®, a BLACKBERRY® operating system, a LINUX® operating system, and the like. Display device 508 may also comprise software components installed on display device 508 and configured to enable access to various monitoring system 140 components. For example, display device 508 may comprise a web browser (e.g., MICROSOFT INTERNET EXPLORER®, GOOGLE CHROME®, etc.), an application, a micro-app or mobile application, or the like, configured to allow the display device 508 to access and interact with monitoring system 140 (e.g., directly or via a respective UI, as discussed further herein). Thus, a status of each ICBM in the first battery array 110 and the second battery array 210 of the battery system 201 being charged may be checked and/or verified prior to the electric aircraft 200 from FIGS. 3 and 4 taking off. If an ICBM in the second battery array 210 no longer meets the airworthiness standard, an ICBM from the first battery array 110 that does may be swapped out with the ICBM that no longer meets the airworthiness standard.

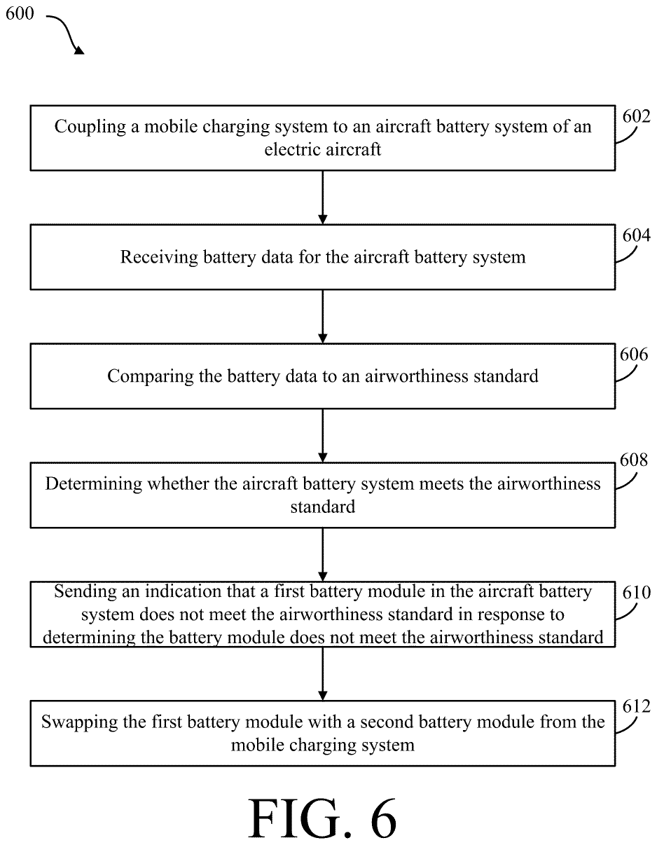

Referring now to FIG. 6, a method 600 for maintaining an aircraft battery system for an electric aircraft is illustrated, in accordance with various embodiments. The method 600 comprises coupling a charging system (e.g., a mobile charging system) to an aircraft battery system of an electric aircraft (step 602). A monitoring system of the charging system may be coupled to a battery management system of the electric aircraft in response to coupling the charging system to the aircraft battery system. In this regard, battery data may be sent from the battery management system of the electric aircraft to the monitoring system.

The method 600 further comprises receiving, via one or more processors of the monitoring system, the battery data for the aircraft battery system (step 604). The battery data may include discharge data, shock and vibration data, whether the ICBM was ever over-discharged, over current, or the like. The battery data can include data corresponding to a single battery module, data corresponding to a string of battery modules, and/or data corresponding to the aircraft battery system overall. The present disclosure is not limited in this regard.

The method 600 further comprises comparing, via the processor, the battery data, and/or data derived therefrom, to an airworthiness standard (step 606). The airworthiness standard may be defined based on discharge data, a time of use, shock and vibration data, a battery capacity threshold, or the like. The capacity threshold may comprise a percentage of rated capacity, absolute capacity (e.g., 1 kWh), or the like. In various embodiments, the airworthiness standard may include mechanical limits (e.g., wear and tear thresholds, or any other limits imposed by certification testing, such as RTCA/DO-160G testing or the like). In various embodiments, the battery system 201 of the electric aircraft 200 may include an available power threshold. In response to the battery system 201 no longer having a potential power supply meeting or exceeding the available power threshold, the battery system 201 (or any limiting modules in the battery system 201) can be replaced, swapped out, or the like, in accordance with various embodiments. The airworthiness standard may further be defined by one of: a number of flight cycles for which the battery modules in the aircraft battery system have been used, a number of hours the battery modules in the aircraft battery system have been used, or the like.

The method 600 further comprises determining whether the aircraft battery system (e.g., overall in its entirety, each string of battery modules, each individual battery module, or the like) meets the airworthiness standard (step 608). In various embodiments, in response to determining the aircraft battery system does not meet the airworthiness standard, the one or more processors may send an indication that the aircraft battery system (e.g., overall in its entirety, a respective string of battery modules, a respective individual battery module, or the like) does not meet the airworthiness standard (step 610). In this regard, a maintenance indication can be generated (and provided to a display device) of the charging system (or the electric aircraft 200), in accordance with various embodiments.

The method 600 may further comprise determining whether a battery module on the charging system meets the airworthiness standard and suggesting a specific battery module from the charging system for swapping to the aircraft battery system for replacing the battery module in the aircraft battery system that does not meet the airworthiness standard. In this regard, if the method 600 determines that the aircraft battery system 201 would be airworthy if a battery module were replaced, the method 600 can perform steps 610 and 612 herein to determine a battery module that is capable of being swapped (step 610) and swapping the battery modules (step 612).

Accordingly, the method 600 can further comprise swapping the first battery module with a second battery module from the charging system (step 612). maintenance person may verify the second battery module meets the airworthiness standard by checking a status of the second battery module via the display device. In this regard, the monitoring system may be configured to continuously monitor all battery modules in the charging system as described previously herein.

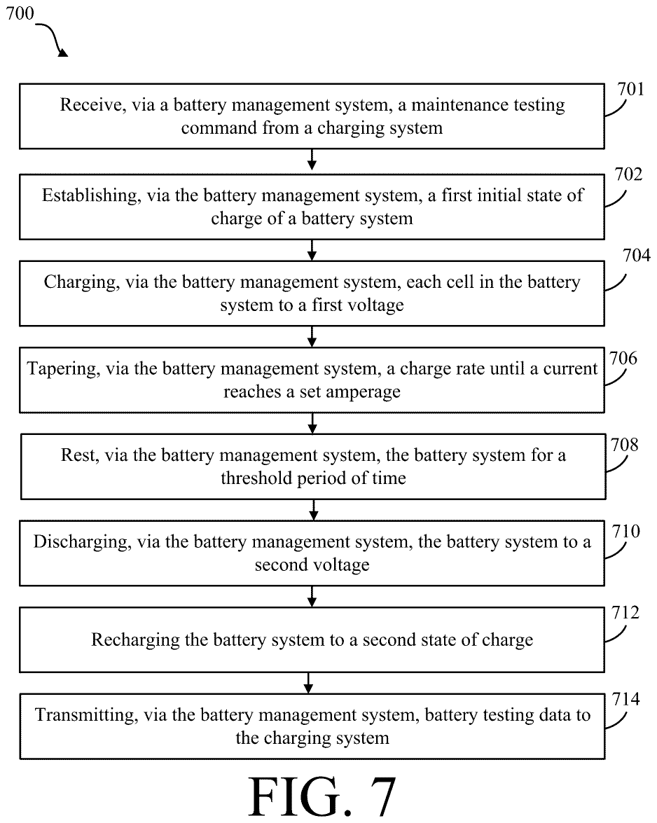

Referring now to FIG. 7, a sub-process (e.g., process 700) for performing a capacity check to determine battery data at step 604 of method 600 is illustrated, in accordance with various embodiments. In various embodiments, the process 700 is performed on-board the electric aircraft 200 from FIG. 3 (e.g., through the battery management system 220 as described further herein). For example, the process 700 comprises receiving, via a battery management system (e.g., the battery management system 220 of the battery system 201 of the electric aircraft 200), a maintenance testing command from a charging system (e.g., from the control system 130 of the charging system 100) (step 701).

In response to receiving the command, the process 700 further comprises establishing, via the battery management system a first initial state of charge (e.g., an open circuit voltage (“OCV”)) of a battery array (e.g., second battery array 210 of the battery system 201 of the electric aircraft 200 from FIG. 3) (step 702). An OCV as referred to herein is a voltage measured between two poles of a battery system (e.g., second battery array 210 of the battery system 201) when the battery system (e.g., the second battery array 210) is not under load (i.e., no current consumption). State of charge is established as a voltage to percentage value predetermined for the type of cell using single cell testing. General methods used for this cell testing may include, for example, hybrid pulse power characterization (“HPPC”) testing.

In various embodiments, the initial state of charge of the battery system is established automatically in response to coupling the charging system 100 from FIG. 3 to the aircraft battery system in step 602 of method 600. For example, in response to electrically coupling the first battery array 110 of the charging system 100 to the second battery array 210 of the battery system 201 and electronically coupling the control system 130 to the battery management system 220, the maintenance testing command can be sent from the control system 130 to the battery management system 220. However, the present disclosure is not limited in this regard. For example, the maintenance testing command can be sent at fixed intervals as described further herein. In various embodiments, the initial state of charge can be anywhere from 0% to 99%, in accordance with various embodiments.

In various embodiments, the process 700 further comprises charging, via the battery management system, each cell in each battery module of the second battery array 210 of the battery system 201 of the electric aircraft 200, at a charging rate (e.g., 1 C), to a first voltage (e.g., approximately 4.45 volts) (step 704). In various embodiments, the charging rate can be a full charging rate (e.g., a maximum charging rate) or the like. In this regard, the charging to the first voltage can occur as quickly as possible. In various embodiments, the first voltage is set at a threshold level below a maximum rated voltage (i.e., a full charge). In various embodiments, the charging rate can be a substantially constant charging rate (e.g., constant+/−5% or the like), or a variable charging rate. The present disclosure is not limited in this regard. In various embodiments, the charging steps disclosed herein can comprise constant current charging, constant power charging, variable current charging, or the like. The present disclosure is not limited in this regard.

In various embodiments, the process 700 further comprises tapering, via the battery management system, the charging until a current reaches a first amperage (e.g., approximately 0.975 amperes) (step 706). In various embodiments, tapering the charging allows the cell (or module) to fully charge to 100% state of charge without exceeding the maximum cell voltage. In various embodiments, a taper of the charging can limit the amount of lithium plating (which is correlated to increased capacity loss) that can occur. In various embodiments, a taper of the charge rate may comprise progressively reducing a current supplied to each cell in the battery module until the first amperage is met. In various embodiments, a rate of charging during in response to the taper of the charging may remain substantially constant (e.g., constant+/−5% or the like). In various embodiments, the charge rate is tapered by controlling a supply voltage from the charging system 100 (e.g., via the bi-directional DC/DC converter 120 from FIG. 3). Although described herein as including a tapering step (step 706), the present disclosure is not limited in this regard. For example, a constant or variable charging without tapering is within the scope of this disclosure.

In various embodiments, in response to the current reaching the first amperage, the charging can be stopped via the battery management system, and the battery system (or battery array) can be allowed to rest for a threshold period of time (e.g., between 20 minutes and 40 minutes, or approximately 30 minutes) (step 708). By allowing the battery module to rest prior to performing a remainder of the process 700, a more accurate, and/or consistent, capacity measurement for the battery array (e.g., the second battery array 210 in the battery system 201 of the electric aircraft 200) can be determined, in accordance with various embodiments. For example, by allowing the battery system (or battery array) to rest prior to a discharging step (e.g., step 710 described further herein), the discharging step can be performed at nominal temperatures for consistency, in accordance with various embodiments. In various embodiments, resting allows the cell (or module) to reach chemical equilibrium which is a good identifier of state of charge.

In various embodiments, the process 700 further comprises discharging, via the battery management system, each cell at a discharge rate (e.g., 1 C) to a second voltage (e.g., approximately 3 volts) (step 710). In various embodiments, the process 700 further comprises recharging, via the battery management system, the battery system (or battery array) to a second initial state of charge (step 712). In various embodiments, the second initial state of charge is approximately the first initial state of charge. However, the present disclosure is not limited in this regard.

In various embodiments, the process 700 further comprises transmitting, via the battery management system, battery testing data (e.g., data from steps 702-712) to the charging system 100 (e.g., to the monitoring system 140 from FIG. 3 and/or the vehicle battery monitoring module 502 from FIG. 5) (step 714). In various embodiments, the charging system 100 may measure the amp hour or energy throughput during the capacity testing. This is performed by a calibrated sensor to verify the capacity measured by the onboard measurement system and provide secondary verification of the capacity. This measured capacity may then be used to update the vehicle BMS capacity reference to correct the on-board capacity reported during flight. Stated another way, calibration of the on-board capacity reference can include updating the on-board reference to the estimated battery capacity determined from the process 700 and/or updating a correction factor for on-board capacity calculations (i.e., to more accurately correlate on-board capacity calculations to off-board capacity calculations performed in accordance with the process 700).

In this regard, the battery data from the testing process (e.g., steps 702-712) can be utilized by process 800 as described further herein to determine a battery capacity for the battery system (or battery array) of the electric aircraft 200 from FIG. 3, in accordance with various embodiments.

In various embodiments, the process 700 from FIG. 7 can be performed at set intervals for a respective electric aircraft 200 from FIG. 3 as described further herein. For example, by performing the process 700 at set intervals, a rate of degradation over time for various battery modules in the battery system (or battery array) can be determined. In various embodiments, by determining typical rates of degradation, a battery module experiencing a higher rate of degradation (e.g., an abnormal rate of degradation) can be determined early in a battery modules life, so the battery module can be removed for maintenance or the like, in accordance with various embodiments. In various embodiments, an “abnormal rate of degradation” as referred to herein is a rate of degradation that is at least two standard deviations outside of a typical rate of degradation. A “typical rate of degradation” can be determined based on a probability distribution performed by the method 1000 as described further herein and can correspond to a normal distribution, in accordance with various embodiments. In this regard, two standard deviations below the mean can be determined based on the probability distribution for rates of battery degradation, in accordance with various embodiments. Although described herein as being at least two standard deviations away from the mean, the present disclosure is not limited in this regard, and any suitable number of standard deviations away from the mean is within the scope of this disclosure.

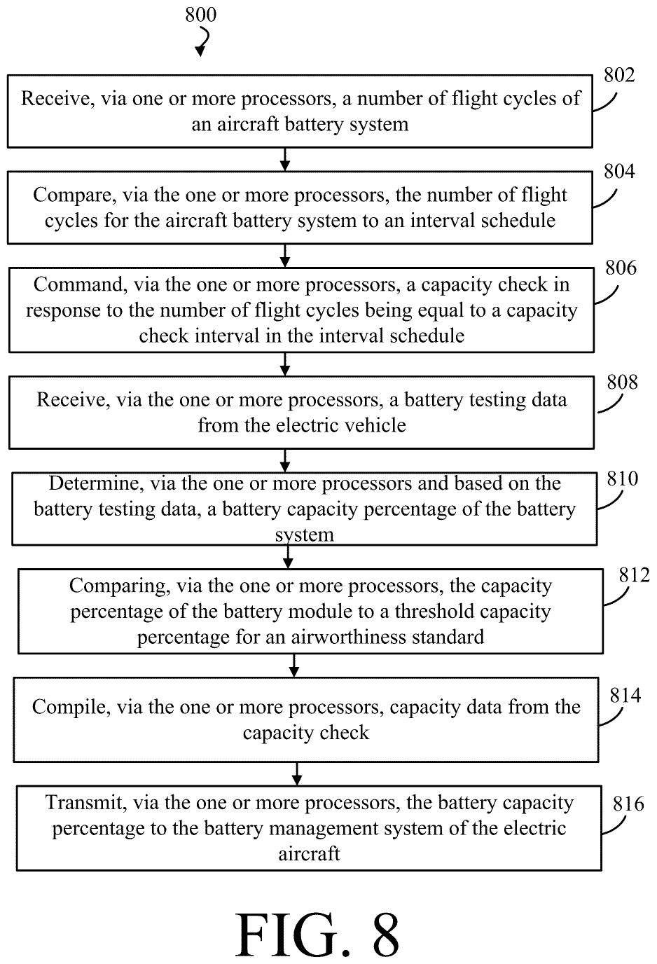

Referring now to FIG. 8, a process 800 performed by the charging system 100 from FIG. 3 is illustrated, in accordance with various embodiments. In various embodiments, the process 800 comprises receiving, via one or more processors, a number of flight cycles of an aircraft battery system (step 802). In various embodiments, each battery system 201 of the electric aircraft 200 from FIG. 3 can be configured to track a number of flight cycles for the aircraft battery system. For example, the aircraft battery system can include one or more processors (e.g., in the battery management system 220 from FIG. 5 or the like) that is configured to count each time the battery system 201 has powered an electric aircraft for a respective flight cycle. In various embodiments, the one or more processors can determine a flight cycle has occurred based on various parameters (e.g., from being charged from below a threshold state of charge, from being coupled to a mobile charging system, or the like). The present disclosure is not limited in this regard.

In various embodiments, the process 800 further comprises comparing, via the one or more processors, the number of flight cycles for the aircraft battery system to an interval schedule (step 804). In various embodiments, the interval schedule can be any number of flight cycles. In various embodiments, it may be desirable to obtain more data after a battery module has been newly commissioned. In this regard, the interval schedule can be a shorter time period initially (e.g., every 10 flight cycles, every 20 flight cycles, or the like). In various embodiments, after sufficient data has been obtained for typical battery modules life cycles, the time period can be extended. In this regard, the time period eventually could be every 100 flight cycles, every 200 flight cycles or the like. The present disclosure is not limited in this regard.

In various embodiments, the process 800 further comprises conducting, via the one or more processors, a capacity check in response to the number of flight cycles being equal to a capacity check interval in the interval schedule (step 806). For example, if the interval schedule is once every 20 flight cycles, the capacity check can be performed after 20 flight cycles, after 40 flight cycles, after 60 flight cycles and so on. In various embodiments, step 806 can comprise performing the process 700 from FIG. 7. In this regard, at each interval in the interval schedule, the process 700 from FIG. 7 can be performed to determine a battery capacity percentage for each battery module in the aircraft battery system, and the battery capacity percentage can be compared to an airworthiness standard as described previously herein.

In various embodiments, the process 800 further comprises receiving, via the one or more processors, a battery testing data from the electric vehicle (e.g., battery testing data from step 714 of process 700) (step 808).

In various embodiments, in response to receiving the battery testing data from steps 702-710 of process 700, a battery capacity percentage of the battery system (or battery array) can be determined via the one or more processors (step 810). For example, a measured capacity and energy of the battery system (or battery array) can be determined based on the following equations:

$$Q = {\int }_{0}^{t} I dt \qquad [ eq . 1 ]$$

$$E = {\int }_{0}^{t} I \cdot t dt \qquad [ eq . 2 ]$$

$$A = \frac{Q ( z )}{Q ( 0 )} \qquad [ eq . 3 ]$$

Where Q is capacity, I is current, t is time, E is energy, A is a capacity percentage (i.e., a relative capacity to a rated capacity), Q(0) is a rated capacity, and Q(z) is a capacity at time where t=z. Based on the above equations, a battery capacity percentage can be calculated in response to the process 700 and compared to a threshold battery capacity percentage for airworthiness.

In various embodiments, the process 800 further comprises comparing, via the one or more processors, the capacity percentage of the battery system (or battery array) to a threshold capacity percentage for an airworthiness standard (step 812). In this regard, the capacity percentage of the battery module can be continuously monitored during ground operations of an electrically powered aircraft (e.g., electric aircraft 200 from FIG. 3), in accordance with various embodiments.

In various embodiments, the process 800 can further comprise compiling, via the process (e.g., through a database or the like), capacity data from the capacity check (step 814). In this regard, capacity data for each battery system 201 can be compiled and stored to make future testing determinations, to certify various battery modules, or the like.

In various embodiments, the process 800 can further comprise transmitting, via the one or more processors, the battery capacity percentage of the battery system (e.g., determined in step 810) to the battery management system 220 of the electric aircraft 200 (step 816). In this regard, the battery management system 220 can calibrate a capacity percentage determined by the battery management system 220 during flight based on the capacity percentage determined from the processes 700, 800 described herein, in accordance with various embodiments. In various embodiments, by regularly calibrating a capacity percentage that is measured by the battery management system 220 during flight based on the processes 700, 800 disclosed herein, a more accurate capacity percentage may be provided (e.g., via a cockpit display or the like in the electric aircraft 200). In various embodiments, the charging system 100 may measure the amp hour or energy throughput during the capacity testing (i.e., process 700). This can be performed by a calibrated sensor to verify the capacity measured by the onboard measurement system of the battery management system 220 and provide secondary verification of the capacity. This measured capacity may then be used to update the vehicle BMS capacity reference to correct the on-board capacity reported during flight.

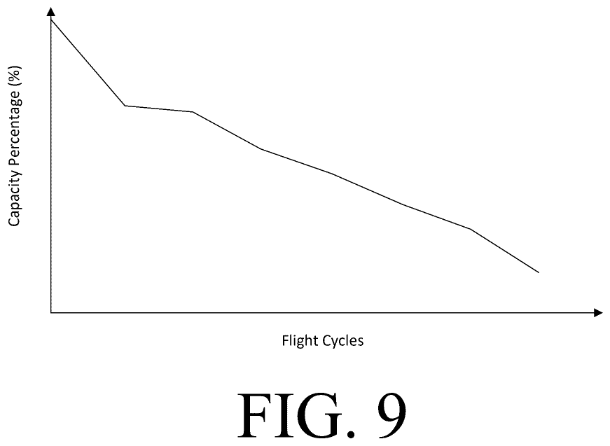

Referring now to FIG. 9, a plot of capacity percentage as a function of flight cycles for an aircraft battery system (e.g., battery system 201 from FIG. 3), is illustrated, in accordance with various embodiments. As shown in FIG. 9, the flight cycle interval could be every 200 flight cycles; however, the present disclosure is not limited in this regard.

In various embodiments, by compiling data for each aircraft battery system in accordance with the process 800 from FIG. 8, a probability distribution can be generated for typical rate of degradation, typical number of flight cycles until a battery system no longer meets the airworthiness standard, a minimum number of flight cycles before a battery module in the aircraft battery system is likely to no longer meet airworthiness, or the like. In this regard, based on the probability distribution, a future interval schedule can be adjusted to provide fewer capacity checks, in accordance with various embodiments.

There is a connection to the accuracy of a reported capacity during vehicle operations (e.g., as measured and/or determined by the battery management system 220 of the electric aircraft 200). The frequency of the capacity test can increase the accuracy of the reported capacity and reduce the need for conservative capacity reporting on the electric aircraft 200, in accordance with various embodiments.

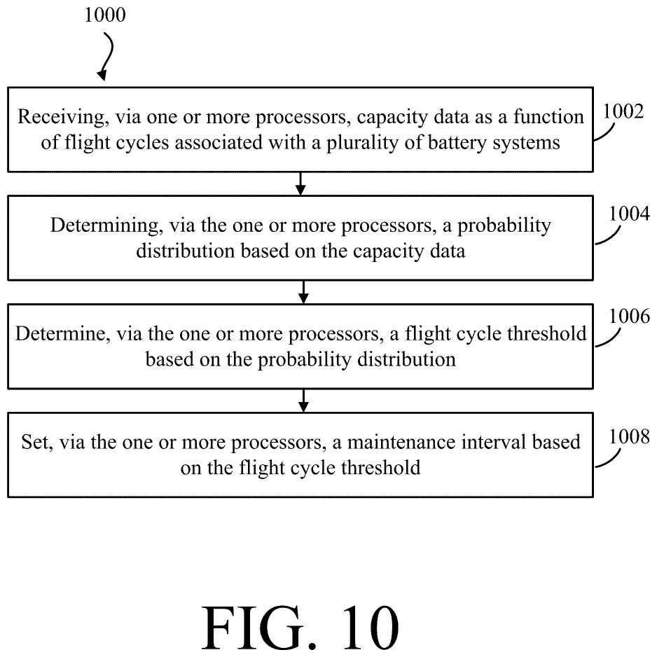

Referring now to FIG. 10, a method 1000 for setting a maintenance interval for a commissioned battery system (e.g., battery system 201) for an electric aircraft 200 is illustrated, in accordance with various embodiments. The method 1000 can be performed by the monitoring system 140 from FIG. 3, the commissioning module 506, or the like. The present disclosure is not limited in this regard. In various embodiments, the method 1000 can be performed by a separate system where data from the process 800 is aggregated across various charging systems for a respective battery system 201 of an electric aircraft 200.

The method 1000 comprises receiving, via one or more processors, capacity data as a function of flight cycles associated with a plurality of battery systems (step 1002). Although described herein as flight cycles, the present disclosure is not limited in this regard. For example, flight time (e.g., flight hours), or the like could also be tracked. In various embodiments, the capacity data is received in response to the process 800 being performed over numerous battery systems for different aircrafts all utilizing a commissioned battery system (i.e., a battery system that has passed testing and development and been commissioned as airworthy). In various embodiments, the capacity data includes a statistically significant number of battery systems (e.g., greater than 100 battery systems, or greater than 1,000 battery systems, or greater than 10,000 battery systems).

In various embodiments, each battery system that is included in the capacity data was tested at set intervals in accordance with process 800 from FIG. 8 via the capacity check process 700 from FIG. 7 until the battery system no longer met an airworthiness. In this regard, the capacity data of method 1000 includes testing data for a statistically significant number of battery systems, that have performed battery tests via process 700 at set intervals in accordance with process 800 for an airworthy life cycle of the battery system. An “airworthy life cycle of a battery system” as disclosed herein, refers to a life cycle of a battery system from rated capacity (i.e., as newly manufactured), until a capacity percentage of the battery system drops below a threshold capacity percentage to be considered airworthy.

In various embodiments, the method 1000 further comprises generating, via the one or more processors, a probability distribution based on the capacity data (step 1004). In various embodiments, the probability distribution is a statistical function that describes all the measured airworthy life cycles from the capacity data for the commissioned battery systems of an electric aircraft (e.g., battery system 201 of the electric aircraft 200). In various embodiments, based on the probability distribution, a standard deviation can be determined.

In various embodiments, the method 1000 further comprises determining, via the one or more processors, a flight cycle threshold based on the capacity data (step 1006). In various embodiments, the flight cycle threshold can correspond to a statistically significant likelihood that the battery capacity percentage is above the threshold battery capacity percentage for the airworthiness standard. For example, for a normal distribution, three standard deviations below the mean will occur only 0.15% of the time (i.e., 15 in 10,000 times), and four standard deviations below the mean will occur only 0.05% of the time (i.e., 5 in 10,000 times).

Therefore, based on the capacity data and the flight cycle threshold, a maintenance interval can be set via the one or more processors (step 1008). In this regard, after a statistically significant amount of data is obtained for battery system 201 of an electric aircraft 200 as described previously herein, the maintenance interval can be set via the method 1000 and the capacity check process 700 from FIG. 7 and the capacity check process 800 from FIG. 8 can be ceased for any commissioned battery systems that are in service. In this regard, a maintenance (or ground) time for an electric aircraft 200 can be reduced once the maintenance interval has been set in accordance with the method 1000.

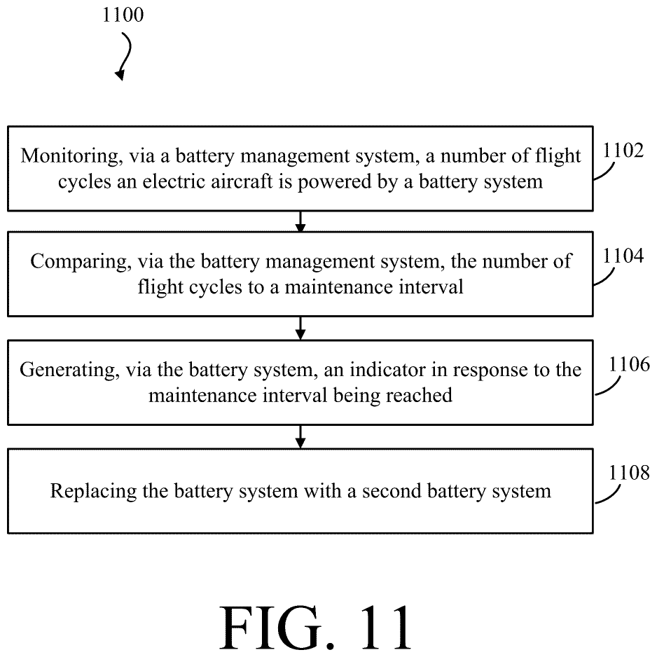

Referring now to FIG. 11, a method 1100 for determining when to replace a battery system for an electrically powered aircraft (e.g., electric aircraft 200) is illustrated, in accordance with various embodiments. The method 1100 comprises monitoring, via a battery management system, a number of flight cycles (or flight time) an electric aircraft is at least partially powered by a battery system (or battery array) (step 1102). In this regard, the battery management system 220 of the electric aircraft 200 from FIG. 3 can store a number of flight cycles (or flight time) associated with the second battery array 210 of the battery system 201 continuously during the airworthy life cycle of the battery system 201.

In various embodiments, the battery system can compare the number of flight cycles to a maintenance interval (step 1104). The maintenance interval can be set based on the method 1000 from FIG. 10. In this regard, the maintenance interval can be associated with an anticipated number of flight cycles where a battery capacity percentage of the battery system is expected to be approaching a battery capacity threshold associated with airworthiness. In this regard, the regular maintenance interval testing of process 700 may no longer be performed, preventing additional degradation of the battery systems and reducing ground maintenance time, in accordance with various embodiments.

In various embodiments, the method 1100 further comprises generating, via the battery system, an indicator in response to the maintenance interval being reached (or exceeded) (step 1106). In various embodiments, the indicator can be a light display in a cockpit of the electric aircraft, or an indicator in the charging system 100 from FIG. 3. The present disclosure is not limited in this regard. If the indicator is in a cockpit of the electric aircraft, the indicator can turn “ON” in response to the number of flight cycles (or flight time) reaching the maintenance interval. In various embodiments, if the indicator is in the charging system 100, the indicator can turn “ON” in response to maintenance interval being reached in accordance with step 1104 and the charging system 100 being coupled to the electric aircraft 200 from FIG. 3 as described previously herein.

In various embodiments, the method 1100 further comprises replacing the battery system with a second battery system (step 1108). In various embodiments, the second battery system can be a newly manufactured battery system having a rated capacity for the battery system. In various embodiments, as described previously herein, the battery modules of the battery system being replaced can be re-purposed for use in the first battery array 110 of the charging system 100. In this regard, the battery modules being replaced can have a secondary life on the charging system 100, in accordance with various embodiments. In various embodiments, each battery module in the battery system being replaced can be individually tested. Based on percentage capacity of a battery module, the battery module could potentially be combined with other battery modules having similar capacity to be re-purposed for a used battery system on an electric aircraft 200 if the battery module still has a remaining useful life. In this regard, battery modules with similar remaining life can be re-purposed together to form a battery system 201 of an electric aircraft 200 from FIG. 3, in accordance with various embodiments.

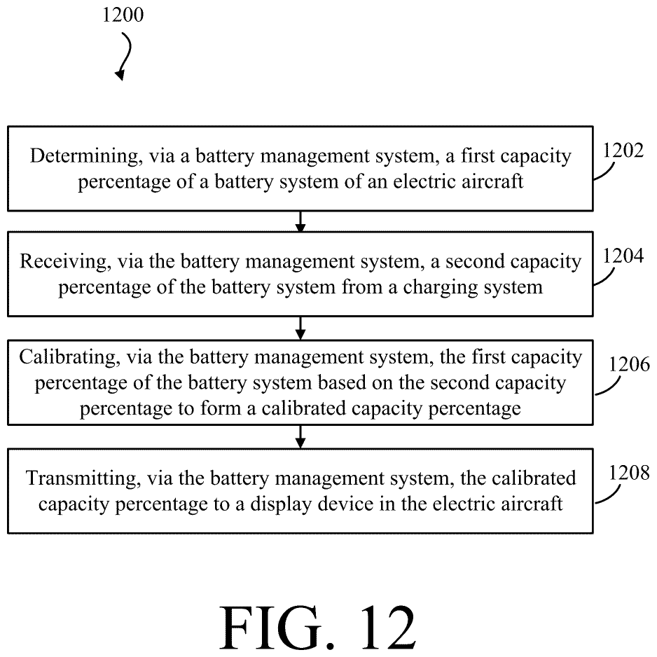

Referring now to FIG. 12, a process 1200 for calibrating a capacity percentage of a battery system 201 for an electric aircraft 200 is illustrated, in accordance with various embodiments. The process 1200 comprises determining, via a battery management system 220, a first capacity percentage of a battery system 201 of an electric aircraft 200 (step 1202). In this regard, the battery management system 220 can include an on-board measurement system configured to measure and calculate an estimated capacity percentage of the battery system 201 during normal operation. In various embodiments, measurements from the on-board measurement system can vary in accuracy due to battery data varying from various flight plans, discharge rates, temperatures, or the like. In this regard, the process 1200 disclosed herein facilitates calibrating testing from the on-board measurement system based on the capacity check processes 700, 800 disclosed herein, which can be performed under ideal testing conditions via the charging system 100, in accordance with various embodiments.

The process 1200 further comprises receiving, via the battery management system 220, a second capacity percentage of the battery system 201 from a charging system 100 (step 1204). In various embodiments, the second capacity percentage can be received after performing the capacity check process 700. In this regard, the second capacity percentage determination can be performed under repeated testing conditions configured to determine a more accurate capacity percentage estimate relative to typical capacity check methodology as described previously herein.

The process 1200 further comprises calibrating, via the battery management system 220, the first capacity percentage of the battery system to a calibrated capacity percentage based on the second capacity percentage (step 1206), and transmitting, via the battery management system the calibrated capacity percentage to a display device in the electric aircraft (step 1208). In this regard, each time that the capacity check of process 700 is performed for an aircraft, the capacity percentage, as determined by the battery management system 220 of the electric aircraft 200, can be calibrated based on the process 700 to ensure that the capacity percentage displayed within the electric aircraft 200 is as accurate as possible. In various embodiments, by performing the process 1200, the battery system 201 of electric aircraft 200 can potentially have a longer life cycle, as accurate capacity data is used throughout the life cycle of the battery system 201, in accordance with various embodiments.

While the principles of this disclosure have been shown in various embodiments, many modifications of structure, arrangements, proportions, elements, materials, and components (which are particularly adapted for a specific environment and operating requirements) may be used without departing from the principles and scope of this disclosure. These and other changes or modifications are intended to be included within the scope of the present disclosure and may be expressed in the following claims.

The present disclosure has been described with reference to various embodiments. However, one of ordinary skill in the art appreciates that various modifications and changes can be made without departing from the scope of the present disclosure. Accordingly, the specification is to be regarded in an illustrative rather than a restrictive sense, and all such modifications are intended to be included within the scope of the present disclosure. Likewise, benefits, other advantages, and solutions to problems have been described above regarding various embodiments.

However, benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

When language similar to “at least one of A, B, or C” or “at least one of A, B, and C” is used in the claims or specification, the phrase is intended to mean any of the following: (1) at least one of A; (2) at least one of B; (3) at least one of C; (4) at least one of A and at least one of B; (5) at least one of B and at least one of C; (6) at least one of A and at least one of C; or (7) at least one of A, at least one of B, and at least one of C.

1. A battery management system including a tangible, non-transitory computer-readable storage medium having instructions stored thereon that, in response to execution by one or more processors, cause the one or more processors to perform operations comprising:
performing, by the one or more processors, a capacity check cycle on a battery system, the battery system configured to power a propulsion system of an electrically powered aircraft, the capacity check cycle including:
establishing, by the one or more processors, a first initial state of charge of the battery system,
charging, by the one or more processors and through a charging system, the battery system to a first voltage,
tapering, by the one or more processors, the charging of the battery system from the charging system until a current reaches a set amperage, and
discharging, by the one or more processors, the battery system to a second voltage; and
calculating an estimated battery capacity of the battery system based on battery data from the capacity check cycle.

2. The battery management system of claim 1, wherein the operations further comprise transmitting, by the one or more processors, the estimated battery capacity of the battery system to the charging system.

3. The battery management system of claim 1, wherein the operations further comprise allowing, by the one or more processors, the battery system to rest between the tapering of the charging and the discharging the battery system for a period of time prior to the discharging the battery system.

4. The battery management system of claim 3, wherein an average temperature of the battery system falls below a threshold average temperature in response to the allowing the battery system to rest.

5. The battery management system of claim 4, wherein the threshold average temperature is less than 90 °F (32.2 °C).

6. The battery management system of claim 1, wherein the discharging the battery system is at a substantially constant rate of discharge.

7. The battery management system of claim 1, wherein the operations further comprise recharging, by the one or more processors and through the charging system, the battery system to a second initial state of charge.

8. The battery management system of claim 1, wherein the operations further comprise receiving, by the one or more processors, a maintenance testing command from the charging system prior to performing the capacity check cycle.

9. The battery management system of claim 1, further comprising updating a displayed battery capacity of the battery system with the estimated battery capacity of the battery system.

10. A battery power management unit for the electrically powered aircraft, the battery power management unit comprising:
the battery management system of claim 1; and
the battery system in electrical communication with the battery management system, the battery system configured to power the propulsion system of the electrically powered aircraft.

11. The charging system, comprising:
the battery management system of claim 1; and
a charging battery system electrically coupled to the battery management system, the charging battery system configured to charge the battery system that is configured to power the propulsion system of the electrically powered aircraft.

12. The battery management system of claim 1, further comprising repeating the performing the capacity check cycle on the battery system after a set operational interval.

13. The battery management system of claim 1, wherein the operations further comprise:
comparing the estimated battery capacity of the battery system to a threshold capacity of the battery system; and
generating an alert in response to the estimated battery capacity falling below the threshold capacity of the battery system.

14. The battery management system of claim 13, wherein the threshold capacity of the battery system is associated with an airworthiness standard for the battery system.

15. The battery management system of claim 1, wherein the operations further comprise:
repeating, by the one or more processors, the performing the capacity check cycle for a plurality of battery systems, each of the plurality of battery systems corresponding to the electrically powered aircraft configured to be powered by the respective battery system in the plurality of battery systems, and
compiling, by the one or more processors, a capacity data for each of the plurality of battery systems.

16. The battery management system of claim 15, wherein the operations further comprises:
determining, by the one or more processors, a probability distribution based on the capacity data for each of the plurality of battery systems; and
determining a maintenance interval for a newly manufactured set of battery systems based on the probability distribution.

17. The battery management system of claim 16, wherein the maintenance interval is based on a confidence level of a capacity of each of the newly manufactured set of battery systems being above a threshold capacity after the maintenance interval.

18. The battery management system of claim 1, wherein the operations further comprise:
receiving, by the one or more processors, a second estimated battery capacity from an aircraft battery management system, the second estimated battery capacity calculated by the aircraft battery management system during operation of the electrically powered aircraft; and
calibrating, by the one or more processors, the estimated battery capacity based on the second estimated battery capacity.

19. The battery management system of claim 18, wherein the operations further comprise transmitting the estimated battery capacity to a display device in a cockpit of the electrically powered aircraft.

20. The battery management system of claim 1, wherein the performing the capacity check cycle is facilitated by shuttling current between the charging system and the battery system through a bi-directional direct current (DC)/DC converter.

21-48. (canceled)
